(19) United States
(12) Patent Application Publication
(10) Pub. No.: US 2016/0226468 A1
(43) Pub. Date: Aug. 4, 2016

(54) METHOD AND APPARATUS FOR PARALLELIZED QRD-BASED OPERATIONS OVER A MULTIPLE EXECUTION UNIT PROCESSING SYSTEM

(71) Applicant: HUAWEI TECHNOLOGIES CO., LTD., Shenzhen (CN)

(72) Inventors: Yiqun GE, Kanata (CA); Wuxian SHI, Kanata (CA); Lan HU, Ottawa (CA)

(21) Appl. No.: 14/610,365

(22) Filed: Jan. 30, 2015

(51) Int. Cl. H03H 21/00

(52) U.S. Cl. CPC H03H 21/0012

(57) ABSTRACT

Methods and apparatuses relating to QR decomposition using a multiple execution unit processing system are provided. A method includes receiving input values at the processing system and generating a first set of values based on the input values, where at least some of the first values are computed in parallel. A second set of values are generated recursively based on values in the first set. A third set of values are generated based on values in the second set, where at least some of the values in the third set are computed in parallel. The recursive component may be simplified to consist of one or more low latency operations. The processing performance of operations relating to QR decomposition may therefore be improved by using the parallelism available in multiple execution unit systems.

### FIELD OF THE DISCLOSURE

The present disclosure relates generally to parallel processing, and more particularly to QR decomposition based processing in multiple core processors.

### BACKGROUND

The linear least squares algorithm is widely used in signal processing, for example in channel estimation, timing synchronization, etc. A least squares problem is often solved using a QR decomposition (QRD) approach. QR decomposition is a linear algebraic method whereby a given matrix A is decomposed into a product, Q·R, such that A=QR.

Several techniques exist for performing QR decomposition. These include Gram-Schmidt orthogonalization, Householder transformations, and Givens rotations.

A limitation of some existing QRD-based algorithms is that they are not well suited for parallelized execution in parallel processing systems, such as for example multi-core processors. Ways of increasing the degree of parallelism in QRD-based algorithms are being explored.

### SUMMARY

In at least one aspect, the present disclosure is directed to a method for adapting a filter in signal processing, the method comprising generating values vᵢ based on values uᵢ in an input signal, the values vᵢ being generated in parallel, where i=0, 1, 2, . . . , N, u_{N}=d, wherein d is an output signal received from the filter, generating values Γ₁ recursively based on the values vᵢ, generating values D(i) and L(i) based on values sᵢ and the values Γᵢ, the values D(i) and L(i) being generated in parallel, where the values sᵢ are conjugates or complex conjugates of the values uᵢ, and generating a signal W according to the values uᵢ, D(i) and L(i).

In at least another aspect, the present disclosure is directed to an apparatus for adapting a filter in signal processing, the apparatus comprising a processing module comprising a first module for receiving value d from the filter and values uᵢ in an input signal, and a second module for generating a signal W and comprising multiple execution units, the second module configured to generate values vᵢ based on values uᵢ, the values vᵢ being generated in parallel using at least some of the multiple execution units, where i=0, 1, 2, . . . , N, u_{N}=d, generate values Γᵢ recursively based on the values vᵢ, generate values D(i) and L(i) based on values sᵢ and the values Γᵢ, the values D(i) and L(i) being generated in parallel using at least some of the multiple execution units, where the values sᵢ are conjugates or complex conjugates of the values uᵢ, and generate the signal W according to the values uᵢ, D(i) and L(i).

In at least another aspect, the present disclosure is directed to a computer-readable storage medium storing instructions that when executed by multiple execution units cause the multiple execution units to perform operations for adapting a filter in signal processing, the operations comprising generating values vᵢ based on values uᵢ in an input signal, the vᵢ values being generated in parallel using at least some of the multiple execution units, where i=0, 1, 2, . . . , N, u_{N}=d, wherein d is an output signal received from the filter, generating values Γᵢ recursively based on the values vᵢ, generating values D(i) and L(i) based on values sᵢ and the values Γᵢ, the values D(i) and L(i) being generated in parallel using at least some of the multiple execution units, where the values sᵢ are conjugates or complex conjugates of the values uᵢ, and generating a signal W according to the values uᵢ, D(i) and L(i).

### BRIEF DESCRIPTION OF THE DRAWINGS

The present disclosure will be better understood having regard to the drawings in which:

FIG. 1A is a representation of an example adaptive signal processing architecture;

FIG. 1B is a representation of an example systolic array that may be used in a QR decomposition;

FIG. 2A is a block diagram representing an example multi-core processor;

FIG. 2B is a block diagram representing an example processing system;

FIG. 3A is generic source code for executing an example loop;

FIG. 3B is a block diagram illustrating a parallelized software model for a multiple execution unit processing system in at least one embodiment;

FIG. 4 is a flow diagram for a process for performing QR decomposition and back substitution with parallelization according to at least one embodiment;

FIG. 5A is a flow diagram for a process for performing QR decomposition and back substitution with parallelization according to at least another embodiment;

FIG. 5B is a flow diagram for a process according to at least another embodiment;

FIG. 6 is a block diagram of an embodiment of a processing system; and

FIG. 7 is a block diagram of an embodiment of a communications device.

### DETAILED DESCRIPTION

The present disclosure is directed in at least one aspect to QR decomposition based methods and systems for execution on a multiple execution unit processing system. The methods may implement a least squares based solution for solving a system of equations. The execution of the methods may be highly parallelized over multiple execution units to improve execution latencies.

Many communication applications must solve or estimate systems of equations. An example system of linear equations, represented as linear system Ax=b, is shown below in equation (1).

$$\begin{matrix}\begin{matrix}{a}_{11} {x}_{1} & + & {a}_{12} {x}_{2} & … & + & {a}_{1 m} {x}_{m} & = & {b}_{1} & + & {e}_{1} \\ {a}_{21} {x}_{1} & + & {a}_{22} {x}_{2} & … & + & {a}_{2 m} {x}_{m} & = & {b}_{2} & + & {e}_{2} \\ … & & … & & & … & & … & & … \\ {a}_{n 1} {x}_{1} & + & {a}_{n 2} {x}_{1} & … & + & {a}_{nm} {x}_{m} & = & {b}_{n} & + & {e}_{n}\end{matrix} & ( 1 )\end{matrix}$$

In equation (1), matrix A (a₁₁, a₁₂, . . . ) is the observations matrix which may be assumed to be noisy, b is vector representing a known sequence (e.g. a training sequence, etc.), x is a vector to be computed by using a least squares method, and e is a vector of residuals or errors. This may be described more compactly in the following matrix notation: Ax=b+e. If there are the same numbers of equations as there are unknowns (i.e. n=m), this system of equations has a unique solution. However, if there are more equations than unknowns (i.e. n>m), then the system of equations is overdetermined and therefore has no single unique solution. For instance, this often occurs in high sampling rate communication applications. The least squares approach may be used to solve this problem by minimizing the residuals e.

In particular, a least squares approach may be used to solve an over-determined linear system Ax=b, where A is an m×n matrix with m>n. The least squares solution x minimizes the squared Euclidean norm of the residual vector r(x)=b−Ax so that

min(∥b−Ax∥₂²) (2)

The least squares solution may be obtained by using a 2-stage QR decomposition-based process.

The basic notion in the solution process begins with the observation that in the case when matrix A is upper triangular, that is, Aᵢⱼ=0 when i<j, then the system can be more easily solved by a process referred to as backward substitution. Backward substitution is a recursive process in which the system may be solved for the last variable first. The process may then proceed to solve for the next to last variable, and so on.

Thus in a 2-stage QR decomposition-based process, a first stage may involve using QR decomposition to convert the linear system Ax=b into the triangular system Rx=Q^{T}b. Q is an orthogonal matrix (Q·Q^{T}=Iₘ) and R is an upper triangular matrix (Rᵢⱼ=0 when i<ⱼ). In a second stage, the triangular system may be solved using back substitution.

The least squares problem may be written using different notation as:

$${argmin}_{\overline{w}} ( {‖ d - {\overline{U}}^{H} \cdot \overline{w} ‖}^{2} ) \qquad ( 3 )$$

where Ū=[u₀, u₁, . . . , u_{N-1}]^{T} is a vector representing an input signal, w̅=[w₀, w₁, . . . , w_{N-1}]^{T} is a vector of N unknown parameters that are to be estimated, d is a reference signal, and ∥d−Ū^{H}·w̅∥ is a Euclidean distance.

In the first stage, a matrix may be constructed for solving the least squares problem:

$$M = {[ \begin{matrix}1 & 0 & 0 & … & 0 & 0 \\ 0 & 1 & 0 & … & 0 & 0 \\ 0 & 0 & 1 & … & 0 & 0 \\ … & … & … & … & … & 0 \\ 0 & 0 & 0 & … & 1 & 0 \\ {u}_{0} & {u}_{1} & {u}_{2} & … & {u}_{N - 1} & d\end{matrix} ]}_{( N + 1 ) \times ( N + 1 )} \qquad ( 4 )$$

again where u₀, u₁, . . . , u_{N-1} are values from input signal vector U, and d is a reference signal.

The M matrix may then be decomposed using QR decomposition according to M=QR, where Q is an orthogonal matrix and R is an upper triangular matrix.

In a second step for solving the least squares problem, backward substitution may be performed according to Wₒₚₜ=R⁻¹, where R⁻¹ is the inverse of matrix R and Wₒₚₜ is an optimal solution.

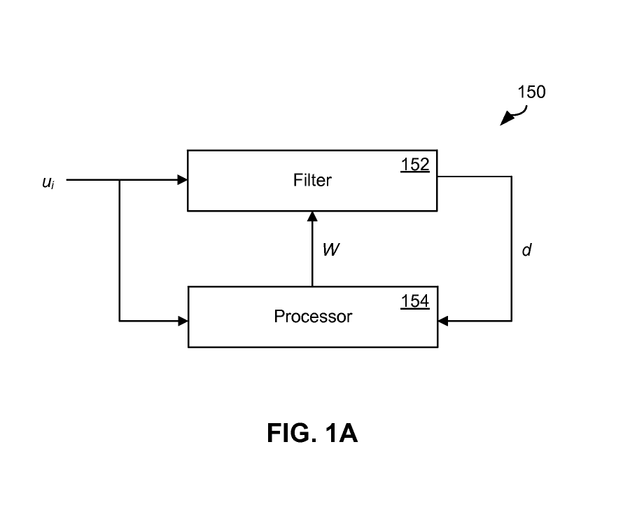

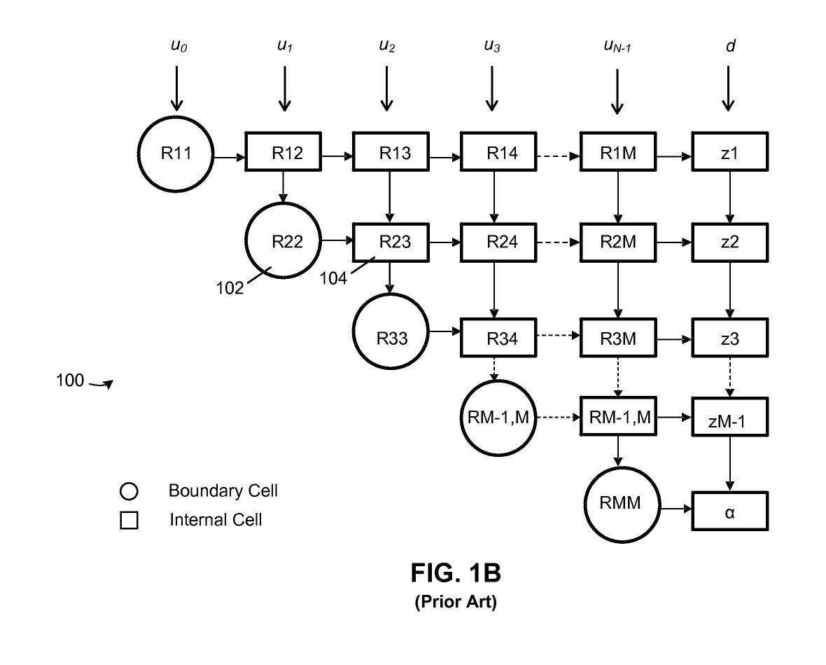

FIG. 1A is a representation of an example adaptive signal processing architecture 150 comprising an adaptive filter 152 and a processing module or system 154. The architecture of FIG. 1A is only an example and is not intended to be limiting. An adaptive filter system may generally have transfer function that is controlled by one or more variable parameters and a way to adjust the one or more variable parameters according to an optimization algorithm. In example architecture 150, an input signal uᵢ may be fed into one or both of filter 152 and processing module 154. Filter 152 may produce and output signal d based on input signal uᵢ. Output signal d may then be fed into processing module 154. In this sense, output signal d may be a reference signal to processing module 154. Processing module 154 generates, based on input signal and output signal d from filter 152, signal W, which may comprise one or more filter coefficients or weights (or changes Δ to coefficients) for controlling or adaptive filter 152.

Embodiments according to the present disclosure may be used with or in association with adaptive signal processing systems or adaptive filters, including but not limited to systems similar to the example architecture of FIG. 1A. Embodiments and teachings according to the present disclosure may also be used in other applications that are based on or use QR decomposition. The present disclosure is therefore not limited to adaptive filtering in signal processing systems.

In fourth Generation networks such as Long Term Evolution (LTE), and in fifth Generation (5G) networks currently in development, least squares algorithms tend to be implemented using floating point arithmetic. Some fourth and fifth generation applications require a higher degree of precision, for example 32-bit true floating point complex signals, compared to previous generations. In addition, longer vectors are generally used because of higher frequencies that are utilized.

As previously mentioned, several techniques exist for performing QR decomposition. These include Gram-Schmidt, Householder, and Givens rotations methods.

The Householder reflection (or transformation) method uses a transformation to obtain the upper triangular matrix R. A reflection matrix, sometimes referred to as a Householder matrix, is used to cancel all the elements of a vector except its first element. The first element is assigned the norm of the vector. Therefore, the columns of an input matrix are treated iteratively to obtain the upper triangular R matrix.

The Givens rotations method uses a number of “Givens” rotations to perform the QR decomposition. Each rotation zeros an element in the subdiagonal of the input matrix, so that a triangular shape R is obtained. The orthogonal Q matrix is formed by the concatenation of all the Givens rotations.

Some existing QRD approaches are implemented in hardware due to the faster computational times that were traditionally achievable in hardware compared to computational times achievable in software.

Some hardware based QRD implementations are based on the Givens rotation algorithm. These are widely used to handle large dimension matrix inversions and QR decompositions, especially for fixed point arithmetic implementations such as Coordinate Rotation Digital Computer (CORDIC) based matrix inversions.

These hardware implementations are typically based on the Givens rotations algorithm since this algorithm generally provides better numerical stability and increased hardware parallelism compared to Gram-Schmidt and Householder based approaches. Some implementations that are based on the Householder algorithm provide a similar degree of numerical stability, but allow for a lower level of hardware parallelism.

Some existing hardware QRD approaches that are based on the Givens rotation method use the 2-stage approach described above. More specifically, QR decomposition is performed using a systolic array and then the triangular system is solved using back substitution. However, because the Givens rotation based QR decomposition is recursive, the amount of parallelism that is achievable is limited.

Reference is now made to FIG. 1B, which is a representation of an example systolic array 100 that may be used in some existing QR decomposition implementations. Array 100 comprises boundary cells 102 and internal cells 104. The rows of the input vector or matrix (u₀, u₁, u₂, . . . , u_{N-1}) are fed as inputs to cells in the array from the top along with value(s) d. Each cell may be implemented as a CORDIC block. The values in all of the cells are shifted to an adjacent cell all at the same time, for example on a clock cycle. Therefore the fastest possible clock cycle may be determined by the slowest cell. The R values (e.g. R₁₁, R₁₂, R₂₂, etc.) and z values (e.g. z₁, z₂, . . . , z_{M-1}) held in each of the cells once all the inputs have been passed through the array are the outputs from the QR decomposition. These values are subsequently used to derive the coefficients using back substitution.

In a Givens rotations implementation, the rotation at each cell may be calculated as follows. The Givens rotations are used to introduce zeros into a matrix. A Givens rotation matrix rotates the ith and jth elements of a vector v by the angle θ such that cos θ=c and sin θ=s. A Givens rotation matrix is shown here, where the “*” denotes a complex conjugate.

$$[ \begin{matrix}{c}_{n} & {s}_{n}^{*} \\ - {s}_{n} & {c}_{n}\end{matrix} ] \qquad ( 5 )$$

Therefore to determine a Givens rotation matrix, the c and s values may be calculated. In the example, these values as well as r values for the R matrix may be calculated for boundary cells 102 as follows:

$$\begin{matrix}{c}_{n} = \frac{{r}_{n - 1}^{i} ( n , n )}{\sqrt{{{r}_{n - 1}^{i} ( n , n )}^{2} + {\vert {u}_{n - 1}^{i} ( n ) \vert}^{2}}} & ( 6 ) \\ {s}_{n} = \frac{{u}_{n - 1}^{i} ( n )}{\sqrt{{{r}_{n - 1}^{i} ( n , n )}^{2} + {\vert {u}_{n - 1}^{i} ( n ) \vert}^{2}}} & ( 7 ) \\ {r}_{n}^{i} ( n ) = [ {c}_{n} {s}_{n}^{*} ] [ \begin{matrix}{r}_{n - 1}^{i} ( n ) \\ {u}_{n - 1}^{i} ( n )\end{matrix} ] & ( 8 )\end{matrix}$$

Values for internal cells 104 in systolic array 100 may be calculated as follows:

$$[ \begin{matrix}{r}_{n}^{i} ( n , j ) \\ {u}_{n}^{i} ( j )\end{matrix} ] = [ \begin{matrix}{c}_{n} & {s}_{n}^{*} \\ - {s}_{n} & {c}_{n}\end{matrix} ] [ \begin{matrix}{r}_{n - 1}^{i} ( n , j ) \\ {u}_{n - 1}^{i} ( j )\end{matrix} ] \qquad ( 9 )$$

Therefore it may be observed that boundary cells 102 are triggered by input signals u coming from the north (e.g. top of the array), whereas the internal cells 104 are triggered by both the input signals u coming from the north and r values coming from the west (e.g. left of the array).

In some implementations that use systolic arrays, such as the example systolic array of FIG. 1B, one or more impediments exist that limit the amount of execution parallelization that may be achieved. For example, high latency square root and reciprocal operations performed in boundary cells 102 may not generally be performed in parallel. Accordingly, these high latency operations may need to be performed serially, resulting in a very high overall execution latency.

In an alternative, QR decomposition may be performed using a Householder based approach. A matrix M may be triangularized using Householder reflections, which are realized using Householder reflection matrices, Pₙ. Therefore the R matrix in QR decomposition may be determined by R=P·M, where P=ΠPₙ. For matrix M having a size of n×n, R=Pₙ₋₁·Pₙ₋₂·Pₙ₋₃· . . . P₁·M.

This approach involves recursion as Pᵢ is calculated using Pᵢ₋₁ M. Therefore a given reflection matrix Pᵢ generally cannot be calculated until all Pᵢ₋₁, Pᵢ₋₂, P₁₋₃, . . . , P₁ have been calculated. The recursive nature of the calculations of the reflection matrices P presents an obstacle to performing these calculations in parallel.

Furthermore, the back substitution process generally cannot begin until the QR decomposition process is completed. In addition, sufficient memory is usually required to buffer the one or more R matrices until the back substitution can begin.

Accordingly, existing Householder-based systolic array approaches are restricted in terms of the degree of processing parallelism that may be achieved.

Although many existing QRD approaches have been typically implemented in hardware for better performance, advances in hardware, including parallel processing systems such as multi-core processors (e.g. up to 8 or 16 cores) and many-core processors (e.g. more than 16 cores), have made possible software based approaches that are capable of achieving hardware-like performance. A software based solution may be used instead of a hardware based solution, for example to provide one or more of better flexibility and programmability, lower cost, and faster delivery to the end user.

Although the terms multi-core and many-core are used herein, their meanings are not limited to any particular number of cores. In some instances, the terms are used interchangeably.

Improvements in performance that may be gained through the use of a multi-core or many-core processor often depends on the software algorithms used and how the algorithms are implemented. Performance gains are usually limited by the portion of the software that can be executed in parallel simultaneously on the multiple cores.

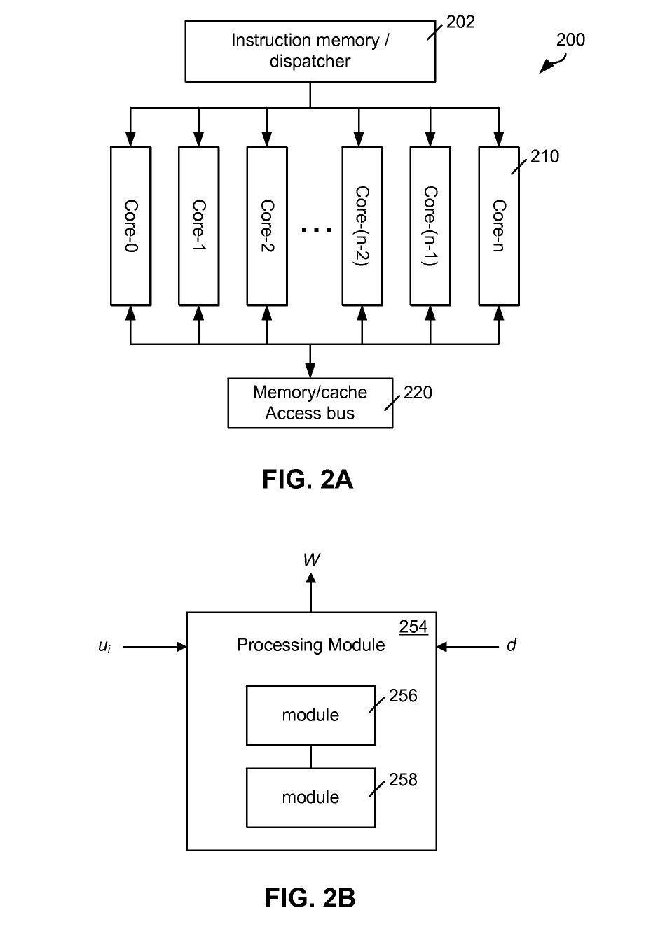

FIG. 2A is a block diagram representing an example multi-core or many-core processor 200 or processing system that may be used with or in one or more embodiments of the present disclosure. For simplicity, only some components of processor 200 are shown. Processor 200 may generally comprise an instruction memory and dispatcher 202, n+1 cores 210 (e.g. cores 0, 1, 2, . . . , n−1, n) or other execution units, and a memory, cache or access bus 220. Cores 210 may have one or more arithmetic logic units (ALUs) (not shown). In addition, some or all of cores 210 may have dedicated access to some resources such as register files, memory ports, among other resources (not shown). In some embodiments, some or all of cores 210 may be synchronized to ensure that they are started and completed at the same clock edge.

An instruction may be provided to one or more cores 210, for example from dispatcher 202. In some instances, the instruction may only differ with regard to a core related index. Thus, one instruction may be fetched to multiple processing cores in parallel, and the processing units of the cores may execute the same instruction, but with a different core related index. Such processing may be used, for example, in a program having a loop, where each iteration of the loop is independent of previous iterations of the loop.

Again, multi-core processor 200 of FIG. 2A is only an example of a parallel processing device that may be used with methods according to the present disclosure. It is contemplated that the present teachings may be used in conjunction with other parallel processing devices and systems.

According to at least one aspect of the present disclosure, a QR decomposition-based least squares algorithm is provided that may be implemented with increased parallelism compared to many existing approaches. The increased parallelism allows the algorithm to take advantage of multiprocessing hardware, such as multi core processors, to achieve increased performance. An increase in performance may be in the form of a shorter execution latency.

An example may be used to demonstrate the improvement in performance that may be achieved using a many-core processor compared to a single core processor, even when the single core processor utilizes pipelining.

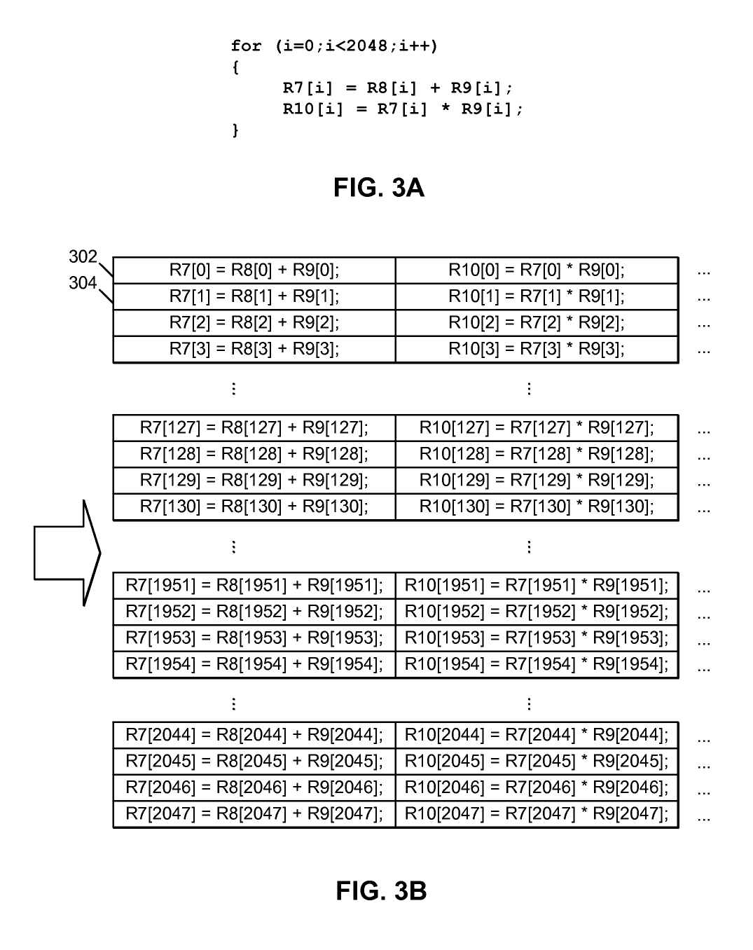

FIG. 3A is generic source code for a process for executing an example loop. The process loops 2,048 times and performs various calculations. In this example, the calculations within each loop are independent of calculations in other iterations of the loop. In particular, a first calculation in the loop of block provides a result that is an addition of two other values (R7[i]=R8[i]+R9[i]). A second calculation includes the sum of the first calculation multiplied by a value (R10[i]=R7[i]*R9[i]). Again, the calculations within each loop (e.g. first and second calculations) are independent of calculations in other iterations of the loop.

When the loop of FIG. 3A is executed in a single execution unit processor, such as a single core processor, only one instruction may be executed at any given time. Even when a single core processor implements pipelining, the instructions are still executed one at a time. When numerous instructions are to be executed, for example in a loop having many iterations, the overall execution latency may be high.

FIG. 3B is a representation of an example many-core processor. In the example, the processor has 2048 cores (or other execution units). An iteration-independent loop, such as the one of FIG. 3A, may be unraveled into multiple independent instruction streams. Each instruction stream may be loaded into a different core so that instructions in the different streams may be executed in parallel. In the example, each iteration of the loop may be considered a separate instruction stream and therefore may be loaded into a different core, assuming there are at least as many cores as there are iterations. Thus for a first iteration where i=0, the instructions R7[0]=R8[0]+R9[0] and R10[0]=R7[0]*R9[0] may be loaded into a first core 302. At the same time for a second iteration where i=1, the instructions R7[1]=R8[1]+R9[1] and R10[1]=R7[1]*R9[1] may be loaded into a second core 304, and so on. In this way, some or all iterations of the loop may be executed in parallel.

In a situation where a processor has fewer cores (or other execution units) than there are instruction streams, processing may still occur in parallel. A first batch or group of instruction streams may be executed followed in time by one or more other groups of instruction streams.

Therefore in at least one embodiment of the present disclosure, an iteration-independent loop in a QR decomposition related process may be unraveled or separated into multiple independent loop bodies. These loop bodies may be processed as separate instruction streams in a parallel manner.

In at least one embodiment of the present disclosure, the QR decomposition is based on a Householder approach instead of on the Givens rotation approach used in some existing QR decomposition methods. In the at least one embodiment, the recursive portion or component of the Householder method is separated from other operations. This allows other operations in the method to be parallelized. Furthermore, in some embodiments, the recursive portion of the Householder method may be simplified, for example into an addition or accumulation operation. As a result, in some embodiments, the size of the memory required and the number of memory accesses are reduced compared to some existing approaches.

In order to solve a system of equations using QR decomposition, a matrix M may be generated:

$$M = {[ \begin{matrix}1 & 0 & 0 & … & 0 & 0 \\ 0 & 1 & 0 & … & 0 & 0 \\ 0 & 0 & 1 & … & 0 & 0 \\ … & … & … & … & … & 0 \\ 0 & 0 & 0 & … & 1 & 0 \\ {u}_{0} & {u}_{1} & {u}_{2} & … & {u}_{N - 1} & d\end{matrix} ]}_{( N + 1 ) \times ( N + 1 )} \qquad ( 10 )$$

where U=[u₀, u₁, . . . , u_{N-1}] is a vector representing an input signal and d is represents a reference signal.

In the example, M has dimensions of (N+1)×(N+1) and is a sparse matrix. Also, all diagonal elements have a value of 1 except for the last diagonal element having a value of d.

The M matrix may then be decomposed using QR decomposition according to M=QR, where Q is an orthogonal matrix and R is an upper triangular matrix. The R matrix has dimensions of (N+1)×(N+1), however we are only interested in the N×N portion of matrix R⁻¹ since the last row and column relate to reference signal d. In addition, the diagonal elements of matrix R⁻¹ may be real valued.

Once matrix M has been decomposed, a coefficient matrix W may be obtained using backward substitution according to Wₒₚₜ=R⁻¹, where R⁻¹ is the inverse of matrix R and Wₒₚₜ is the coefficient matrix representing a solution.

A process according to at least one embodiment of the present disclosure and based on Householder reflections is now described. In the QR decomposition, the R matrix may be computed as follows:

$$R = \underbrace{( {\prod }_{n = N}^{1} {P}_{n} )}_{{P}_{( N + 1 ) \times ( N + 1 )}} \times M \qquad ( 11 )$$

Equation (11) may be represented in matrix notation as:

$${[ \begin{matrix}x & x & x & … & x & x \\ 0 & x & x & … & x & x \\ 0 & 0 & x & … & x & x \\ … & … & … & … & … & … \\ 0 & 0 & 0 & … & x & x \\ 0 & 0 & 0 & … & 0 & x\end{matrix} ]}_{{R}_{( N + 1 ) \times ( N + 1 )}} = P \times {[ \begin{matrix}1 & 0 & 0 & … & 0 & 0 \\ 0 & 1 & 0 & … & 0 & 0 \\ 0 & 0 & 1 & … & 0 & 0 \\ … & … & … & … & … & 0 \\ 0 & 0 & 0 & … & 1 & 0 \\ {u}_{0} & {u}_{1} & {u}_{2} & … & {u}_{N - 1} & d\end{matrix} ]}_{{M}_{( N + 1 ) \times ( N + 1 )}} \qquad ( 12 )$$

Matrix M in equation (12) may be rewritten from R=PM into R=P(I+EU), where I is the identity matrix, E is a vector of all zeros except for the last element, which has a value of 1, and U is a vector of values [u₀, u₁, . . . , u_{N-1}]:

$$P \times ( {[ \begin{matrix}1 & 0 & 0 & … & 0 & 0 \\ 0 & 1 & 0 & … & 0 & 0 \\ 0 & 0 & 1 & … & 0 & 0 \\ … & … & … & … & … & … \\ 0 & 0 & 0 & … & 1 & 0 \\ 0 & 0 & 0 & … & 0 & 1\end{matrix} ]}_{{I}_{( N + 1 ) \times ( N + 1 )}} + {[ \begin{matrix}0 \\ 0 \\ 0 \\ … \\ 0 \\ 1\end{matrix} ]}_{{E}_{( N + 1 ) \times 1}} \cdot \begin{matrix}[ {u}_{0} & {u}_{1} & … & {u}_{N - 1} & {u}_{N} ] \\ & & {U}_{1 \times ( N + 1 )} & & \end{matrix} ) \qquad ( 13 )$$

where u_{N}=d−1.

The equation R=P(I+EU) may be rewritten in the form R=PI+PEU.

Accordingly, the values of matrix R are:

$$R ( i , j ) = \{ \begin{matrix}{u}_{j} \cdot P ( i , N ) & i < j \\ ( 1 + {u}_{i} ) \cdot P ( i , i ) & i = j \\ 0 & others\end{matrix} \qquad ( 14 )$$

The W matrix, which is effectively the inverse of matrix R, namely R⁻¹, may be calculated using back substitution. In the example, this may be computed as follows:

$$W ( i , j ) = \{ \begin{matrix}\frac{1}{( 1 + {u}_{i} ) \cdot P ( i , i )} & i = j \\ - \frac{{u}_{j}}{( 1 + {u}_{j} ) \cdot P ( j , j )} \cdot ( {\sum }_{m = 0}^{j - 1} W ( i , m ) \cdot P ( m , N ) ) & i < j \\ 0 & otherwise\end{matrix} \qquad ( 15 )$$

It is observed in equation (15) that R⁻¹ may be calculated by values P(j,j), which are the diagonal elements of P, as well as by values P(:,N), which are the elements in the last column of P. The determination of R⁻¹ may therefore be reduced to the calculations of the P(j,j) and P(:,N) values. Therefore equation (15) may be rewritten as:

$$W ( i , j ) = \{ \begin{matrix}D ( i ) & i = j \\ - {u}_{j} \cdot D ( i ) \cdot ( {\sum }_{m = 0}^{j - 1} W ( i , m ) \cdot L ( m ) ) & i < j \\ 0 & otherwise\end{matrix} \qquad ( 16 )$$

where W(i, 0) is initialized to zero. Also,

$$D ( i ) = \frac{1}{( 1 + {u}_{i} ) \cdot P ( i , i )} , L ( i ) = P ( i , N ) \qquad ( 17 )$$

The D(i) is representative of the diagonal (“D” for diagonal) element values of P and the L(i) is representative of the last (“L” for last) column of P.

In a Householder-based QR decomposition algorithm, most of the computation required may be for the generation of the n Householder reflection matrices, Pₙ, Pₙ₋₁, Pₙ₋₂, Pₙ₋₃, . . . , P₁.

The calculation of the P matrices involves recursion since a given reflection matrix Pᵢ generally cannot be calculated until all previous Pᵢ₋₁, Pᵢ₋₂, Pᵢ₋₃, . . . , P₁ have been calculated, as previously discussed. As a result, the recursive nature of the calculations of the reflection matrices P presents an obstacle to performing the calculations in parallel.

In at least one embodiment, the recursive portion of the Householder method is separated from other operations. This may allow other operations in the method to be parallelized.

In at least one embodiment, one or both of the D(i) and L(i) values in equations (16) and (17) may be computed in parallel.

Reference is made to the following Householder reflection matrices, P₁ and P₂:

$$\begin{matrix}{P}_{1} = {[ \begin{matrix}\frac{1}{{α}_{1}} & 0 & … & 0 & \frac{{u}_{0}^{*}}{{α}_{1}} \\ 0 & 1 & … & 0 & 0 \\ … & … & … & … & … \\ 0 & 0 & … & 1 & 0 \\ \frac{{u}_{0}}{{α}_{1}} & 0 & … & 0 & - \frac{1}{{α}_{1}}\end{matrix} ]}_{( N + 1 ) \times ( N + 1 )} \\ where & ( 18 ) \\ {α}_{1} = \sqrt{1 + \frac{{‖ {u}_{0} ‖}^{2}}{{α}_{0}^{2}}} & ( 19 )\end{matrix}$$

where α₀=1 and ∥u₀∥² is a squared Euclidean distance input value of u₀ of input signal U, and where:

$$\begin{matrix}{P}_{2} = {[ \begin{matrix}1 & 0 & … & 0 & 0 \\ 0 & \frac{1}{{α}_{2}} & … & 0 & \frac{{u}_{1}^{*}}{{α}_{2}} \cdot \frac{- 1}{{α}_{1}} \\ … & … & … & … & … \\ 0 & 0 & … & 1 & 0 \\ 0 & \frac{{u}_{1}}{{α}_{2}} \cdot \frac{- 1}{{α}_{1}} & … & 0 & - \frac{1}{{α}_{2}}\end{matrix} ]}_{( N + 1 ) \times ( N + 1 )} \\ where & ( 20 ) \\ {α}_{2} = \sqrt{1 + \frac{{‖ {u}_{1} ‖}^{2}}{{\prod }_{m = 0}^{1} {α}_{m}^{2}}} & ( 21 )\end{matrix}$$

Therefore in the generation of Householder matrices P₁, P₂, P₃, . . . , the only recursive component is α.

In a generalized form, for reflection matrix Pₙ:

$${α}_{n} = \sqrt{1 + \frac{{‖ {u}_{n - 1} ‖}^{2}}{{\prod }_{m = 0}^{n - 1} {α}_{m}^{2}}} , \\ {α}_{0} = 1 \qquad ( 22 )$$

which is only dependent on input value uₙ₋₁ and all previous α, namely αₙ₋₁, αₙ₋₂, . . . , α₁.

Using this calculation for α, the D(i) and L(i) values may be calculated by:

$$D ( i ) = \frac{1}{{α}_{i + 1}} , \\ L ( i ) = \frac{{u}_{i}^{*}}{{\prod }_{m = 0}^{i} {α}_{m}^{2}} \qquad ( 23 )$$

again where

$${α}_{n} = \sqrt{1 + \frac{{‖ {u}_{n - 1} ‖}^{2}}{{\prod }_{m = 0}^{n - 1} {α}_{m}^{2}}} , \\ {α}_{0} = 1 \qquad ( 24 )$$

The calculation for αₙ in equation (24) is recursive and therefore is not possible to unroll. Furthermore, the computation includes calculating a reciprocal, a square root, and continual multiplication. This overall computation for αₙ has a long latency.

The recursive calculation for αₙ may be rewritten as:

$$\begin{matrix}{α}_{n} = \sqrt{1 + \frac{{‖ {u}_{n - 1} ‖}^{2}}{{\prod }_{m = 0}^{n - 1} {α}_{m}^{2}}} ⇒ {α}_{n}^{2} \\ = 1 + \frac{{‖ {u}_{n - 1} ‖}^{2}}{{\prod }_{m = 0}^{n - 1} {α}_{m}^{2}} ⇒ {α}_{n}^{2} \cdot {\prod }_{m = 0}^{n - 1} {α}_{m}^{2} \\ = {\prod }_{m = 0}^{n - 1} {α}_{m}^{2} + {‖ {u}_{n - 1} ‖}^{2} ⇒ {\prod }_{m = 0}^{n - 1} {α}_{m}^{2} \\ = {\prod }_{m = 0}^{n - 1} {α}_{m}^{2} + {‖ {u}_{n - 1} ‖}^{2}\end{matrix} \qquad ( 25 )$$

A new variable Γ is introduced and may be defined as:

$${Γ}_{n} = {\prod }_{m = 0}^{n} {α}_{m}^{2} \qquad ( 26 )$$

such that:

$${α}_{n} = \frac{\sqrt{{Γ}_{n}}}{\sqrt{{Γ}_{n - 1}}} \qquad ( 27 )$$

The recursive element of the QR decomposition may therefore be simplified to the following, which comprises an addition or accumulation operation:

Γₙ=Γₙ₋₁+∥uₙ₋₁∥², Γ₀=1 (28)

In equation (28), the term ∥uₙ₋₁∥² is based on input value uₙ₋₁ and therefore may be pre-calculated in parallel. Thus the recursion in equation (28) is simplified so that each instance in the recursion is an addition or accumulation instruction, namely Γₙ=Γₙ₋₁+value. The simplicity and speed of this accumulation instruction is compared to the much slower computation of equation (24). Although equation (28) uses an addition or accumulation, in other embodiments the recursion may include or consist of one or more other operations, such as one or more additions, accumulations, subtractions, multiplications, or other low latency operations, etc. In at least one embodiment, equation (28) may be implemented using a floating point real value accumulation operation.

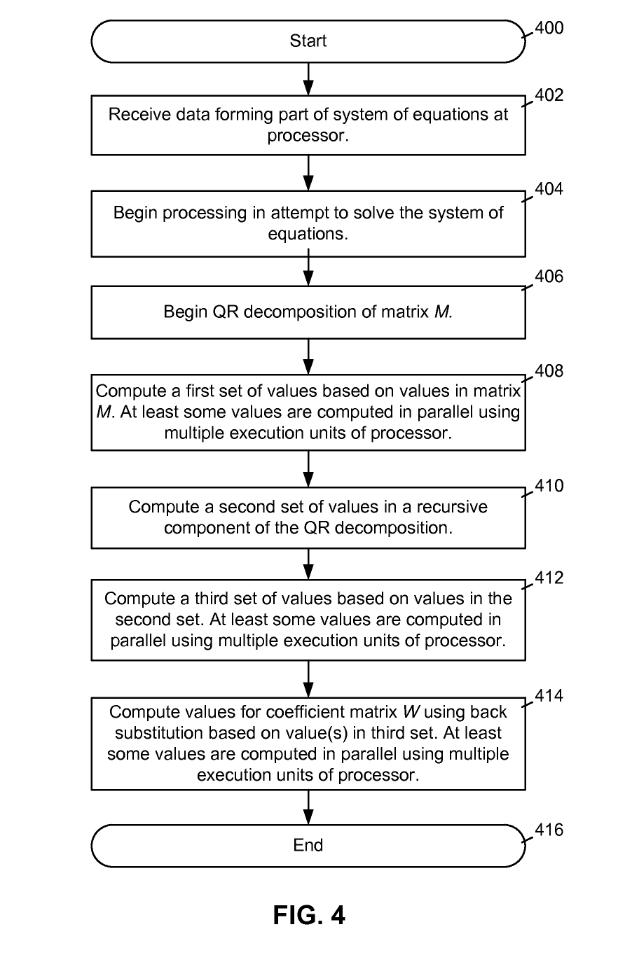

FIG. 4 is a generalized flow diagram for a process for performing QR decomposition and back substitution with parallelization according to at least one embodiment of the present disclosure. The process may be implemented using multiprocessing hardware having multiple execution units, such as for example a multi-core or many-core processor, or a processor having multiple arithmetic logic units (ALUs). In the example of FIG. 4, the process is described with reference to a multi-core processor.

The process begins at block 400 and proceeds to block 402, where data may be received at the multi-core processor. The received data may be symbols or other values, and may be received over multiple streams. The data may form part of a system of equations and may be represented or organized into a matrix M.

The process then proceeds from block 402 to block 404, where processing begins in an attempt to compute a solution to the system of equations. The solution may be calculated in any suitable way, for example using a least squares-based method.

The process then proceeds from block 404 to block 406, where decomposition of matrix M into a unitary Q matrix and an upper triangular matrix R, such that M=QR, may begin.

The process then proceeds from block 406 to block 408, where a first set of values may be computed based on at least some values in matrix M, where at least two values in the first set may be computed in parallel using two or more cores (or other execution units) of the processor.

The process then proceeds from block 408 to block 410, where a second set of values may be computed in a recursive component of the QR decomposition. The second set of values may be computed based on at least some values in the first set. In at least one embodiment, values in the second set may be computed using equation (28) or a similar or equivalent equation. Due to the recursive nature of the calculations, in one embodiment, the calculations may be performed using only one core in the processor.

The process then proceeds from block 410 to block 412, where a third set of values may be computed based on at least some values in the second set. Two or more values in the third set may be computed in parallel using two or more cores (or other execution units) of the processor. In at least one embodiment, values in the third set may comprise one or both of D(i) and L(i) values, which may be computed according to equation (23) or similar or equivalent equations. Furthermore, in at least one embodiment, at least some of the values in the third set may be used to compute upper triangular matrix R.

The process then proceeds from block 412 to block 414, where values for the coefficient matrix W may be computed using back substitution based on at least some values in the third set. Two or more values in the W matrix may be computed in parallel using two or more cores (or other execution units) of the processor. In at least one embodiment, the back substitution may comprise computing the values of at least two rows of the W matrix in parallel using at least two or more cores (or other execution units) of the processor. The rows of the W matrix, as opposed to all values in the W matrix, may be processed in parallel using separate data or instruction streams as the computation of values in each row may be recursive. In other words, in some embodiments, values in row i of matrix W may need to be computed in a recursive manner.

Once the back substitution is completed, the values in the last column of the W matrix may be the w coefficients, which may provide a solution to the system of equations described above in reference to block 402.

The process then proceeds from block 414 to block 416 and ends.

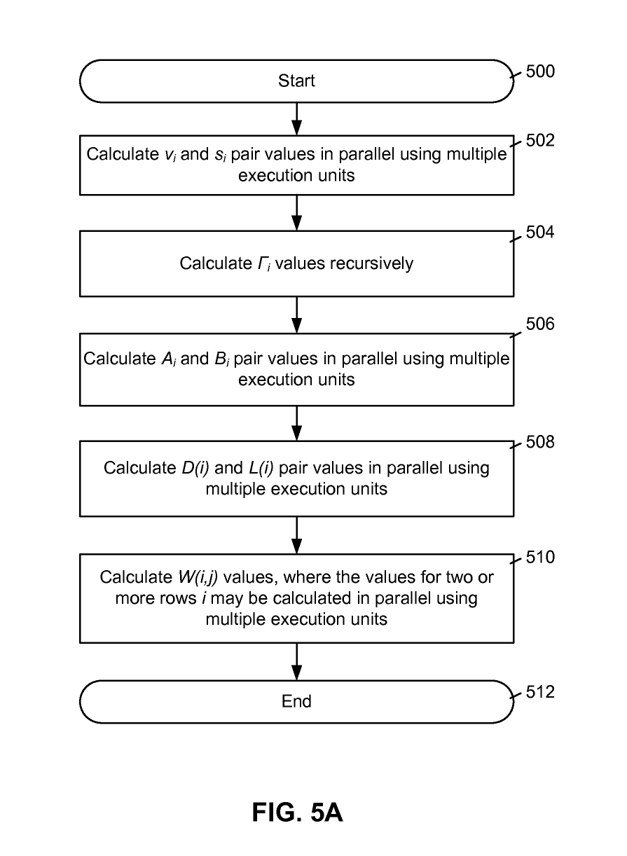

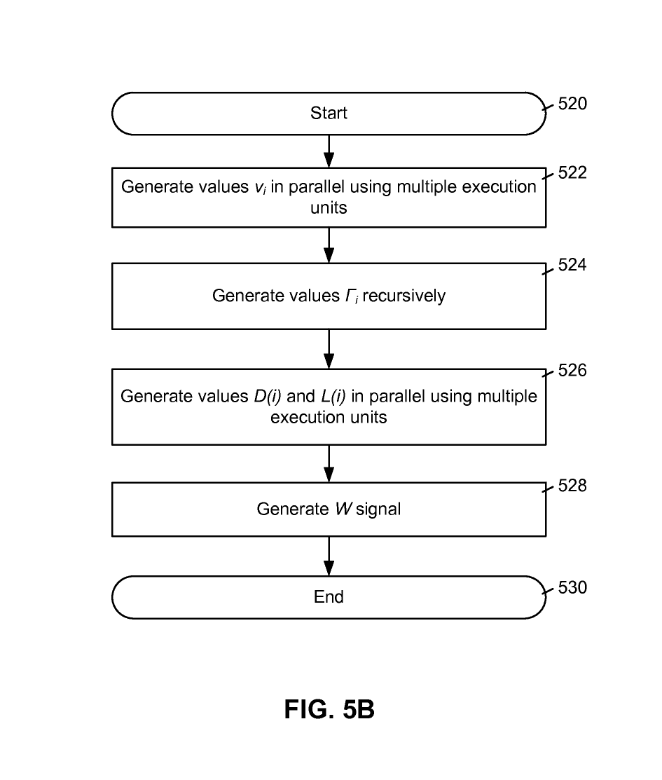

FIG. 5A is a flow diagram for a process for performing QR decomposition and back substitution with parallelization according to at least one embodiment of the present disclosure. The example of FIG. 5A may be similar to the example of FIG. 4 and is described in more detail. The process of FIG. 5A may be implemented using multiprocessing hardware having multiple execution units, such as for example a multi-core or many-core processor, or processor having multiple arithmetic logic units (ALUs).

The process begins at block 500 and proceeds to block 502, where values vᵢ and sᵢ are introduced for the QR decomposition. These values may be defined as follows:

vᵢ=∥uᵢ∥² (29)

sᵢ=uᵢ* (30)
where i=0, 1, 2, . . . , N, u_{N}=d, and * denotes the conjugate or complex conjugate.

The vᵢ and sᵢ values for i=0, 1, 2, . . . , N are calculated. Two or more vᵢ and sᵢ pairs (e.g. having a same i value) may be calculated in an independent loop body. Two or more of these loop bodies may be processed separately but in parallel using different execution units, as previously described. In one embodiment, two or more of these loop bodies may be fed to a different core or ALU of a multi-core processor. For example, v₀ and s₀ may be fed to a first core in a multi-core processor, v₁ and s₁ may be fed a second core, v₂ and s₂ may be fed to a third core, and so on. However, in at least another embodiment, vᵢ and sᵢ computations may be fed to different cores for simultaneous parallel processing, for example v₀ may be fed to a first core, s₀ may be fed to a second core, v₁ may be fed to a third core, s₁ may be fed a fourth core, etc.

Therefore in one example where 16 vᵢ and sᵢ pairs are to be calculated, each pair may be fed to a different core to be calculated in parallel. This assumes that 16 cores are available. If only 8 cores are available, it may be possible to calculate a first 8 vᵢ and sᵢ pairs in parallel, and then calculate the remaining 8 vᵢ and sᵢ pairs thereafter. Other options for calculating these values using multi-processing systems are possible. The number of pairs and cores described are examples only and are not intended to be limiting.

The process proceeds from block 502 to block 504, where the recursive loop of the QR decomposition may be performed. Here, the loop may comprise the basic addition (or accumulation) operation represented by equation (28) above. Thus the recursive loop in the present process may be performed according to:

Γᵢ=Γᵢ₋₁+vᵢ₋₁ (31)
where Γ₀=1 and i=1, 2, 3, . . . , N.

The recursive nature of this loop means that it may be performed serially, for example using only one core or ALU of a multi-core processor.

The process then proceeds from block 504 to block 506, where values Aᵢ and Bᵢ are introduced and may be defined as follows:

$${A}_{i} = \sqrt{{Γ}_{i}} \\ {B}_{i} = \frac{1}{\sqrt{{Γ}_{i}}} \\ where \\ i = 0 , 1 , 2 , 3 , … , N . \qquad ( 32 )$$

Therefore once the Γᵢ values have been computed, the Aᵢ and Bᵢ values may be computed. Although both the square root calculation (for Aᵢ) and the reciprocal calculation (for Bᵢ) take a relatively long time compared to more simple calculations, and therefore are high latency instructions, some or all of these pairs of computations may be performed in parallel. For instance, similar to the computation of the vᵢ and sᵢ pairs described above, each Aᵢ and Bᵢ pair (e.g. having a same i value) may be computed in an independent loop body. Two or more of these loop bodies may be computed separately but in parallel using multiple execution units. In one embodiment, two or more of these loop bodies may be fed to different cores or ALUs of a processor. Therefore rather than performing these long computations for every Aᵢ and Bᵢ pair using a single execution unit, some or all calculations or pair calculations may be performed in parallel to reduce the overall processing time.

The process then proceeds from block 506 to block 508, where D(i) and L(i) values may be calculated using the Aᵢ and Bᵢ values as follows:

D(i)=AᵢBᵢ₊₁

L(i)=sᵢBᵢBᵢ₊₁ (33)
where i=0, 1, 2, 3, . . . , N.

The D(i) and L(i) values were described above in relation to equation (23).

In a similar manner as the calculations performed in blocks 502 and 506, D(i) and L(i) pairs (e.g. having a same i value) may be calculated in independent loop bodies. Two or more of these loop bodies may be processed in parallel using multiple execution units of a processor.

The process then proceeds from block 508 to block 510, where back substitution may be performed using the calculated D(i) and L(i) values according to:

$$W ( i , j ) = \{ \begin{matrix}D ( i ) & i = j \\ - {u}_{j} \cdot D ( i ) \cdot ( {\sum }_{m = 0}^{j - 1} W ( i , m ) \cdot L ( m ) ) & i < j \\ 0 & otherwise\end{matrix} \qquad ( 34 )$$

Equation (34) is the same as equation (16) provided above.

As previously described, the back substitution computation comprises a recursive component. Therefore in some embodiments, back substitution cannot be fully unrolled to calculate all W(i,j) values completely in parallel. However, the back substitution process may be partly parallelized by unrolling the calculation into different instruction streams for each row i of matrix of the R matrix. Each instruction stream for a given row of the R matrix may then be executed in parallel. Another way of describing this is that the back substitution process may be partly parallelized by unrolling the calculation into different instruction streams for each row i of matrix of the W matrix.

Once back substitution is complete, the values in the last column of the W matrix may be the w coefficients, which are a solution to the system or overdetermined system of equations. The process then proceeds from block 510 to block 512 and ends.

FIG. 5B is a flow diagram for another process according to at least one embodiment of the present disclosure. The example of FIG. 5B may be at least somewhat similar to the example process of FIG. 5A and may also be implemented using multiprocessing hardware having multiple execution units.

The process begins at block 520 and proceeds to block 522, where values vᵢ for a QR decomposition may be generated or computed. The values vᵢ may be generated in a way similar to that described in relation to block 502 in the process of FIG. 5A. At least some or all of the values vᵢ may be generated or computed in parallel using at least two multiple execution units.

The process proceeds from 522 to block 524 where a recursive loop of a QR decomposition may be performed. A computation of values Γᵢ may be performed in a similar way as described with reference to block 504 in the process of FIG. 5A.

The process then proceeds from block 524 to block 526 where values D(i) and L(i) may be generated. The generation of one or both of the values D(i) and L(i) may be performed in a way similar to the way described above in relation to block 508 in the process of FIG. 5A. At least some or all of the values D(i) and L(i) may be generated in parallel using at least two multiple execution units.

The process then proceeds from block 526 to block 528 where signal w may be generated or computed according to some or all of values uᵢ, D(i) and L(i). Again, signal W may be computed in a similar way as described above in relation to block 510 of FIG. 5A.

The process then proceeds from block 528 to block 530 and ends.

Although the embodiments of FIG. 4, FIG. 5A and FIG. 5B each show a particular number and order of steps in their respective process, this is not meant to be limiting. For example, the order of the steps, the number of steps, and the steps themselves may be different in other embodiments. The embodiments of FIG. 4, FIG. 5A and FIG. 5B are only examples and are not meant to be limiting.

FIG. 2B is a block diagram representing an example processing module or system 254 according to the present disclosure. Module or system 254 may be used with or in one or more embodiments. For example, module 254 processing may be used in an adaptive filter architecture including but not limited to the architecture of FIG. 1A. For instance, processor block 154 in FIG. 1A may comprise a module or system similar to module 254 in FIG. 2B. In addition, example processing module or system 254 may be used to implement methods or processes similar to or the same as those shown and described in FIG. 4, 5A or 5B. However, it is to be appreciated that a processing module or system according to the present disclosure may be used in other architectures and in other applications.

Having reference to FIG. 2B, processing module or system 254 may comprise one or more sub-modules, for example modules 256 and 258. According to at least one embodiment, processing module or system 254 may comprise a first module 256 and a second module 258. First module 256 may be configured for receiving value d from the filter and values uᵢ in an input signal. Second module 258 may be configured for generating a signal W and comprise multiple execution units. Second module 258 may be further configured to generate corresponding values vᵢ in parallel using at least some of the multiple execution units according to values uᵢ, where i=0, 1, 2, . . . , N, u_{N}=d. In at least one embodiment, all values vᵢ may be generated in parallel. However, in other embodiments, only some values vᵢ may be generated in parallel.

Second module 258 may be further configured to generate corresponding values Γᵢ recursively according to the values vᵢ. Corresponding values D(i) and L(i) may be generated in parallel using at least some of the multiple execution units according to values Γᵢ and values sᵢ, where the values sᵢ are conjugates or complex conjugates of the values uᵢ. In addition, second module 258 may generate the signal W according to the values uᵢ, D(i) and L(i). Signal W may be outputted, for example to be received by a filter.

Although processing module or system 254 is shown as having two modules 256, 258, this is not intended to be limiting. Module 254 may have fewer or more modules or submodules. Furthermore, although the functions described above are described as being performed by one of the two sub modules 256, 258, this also is not meant to be limiting.

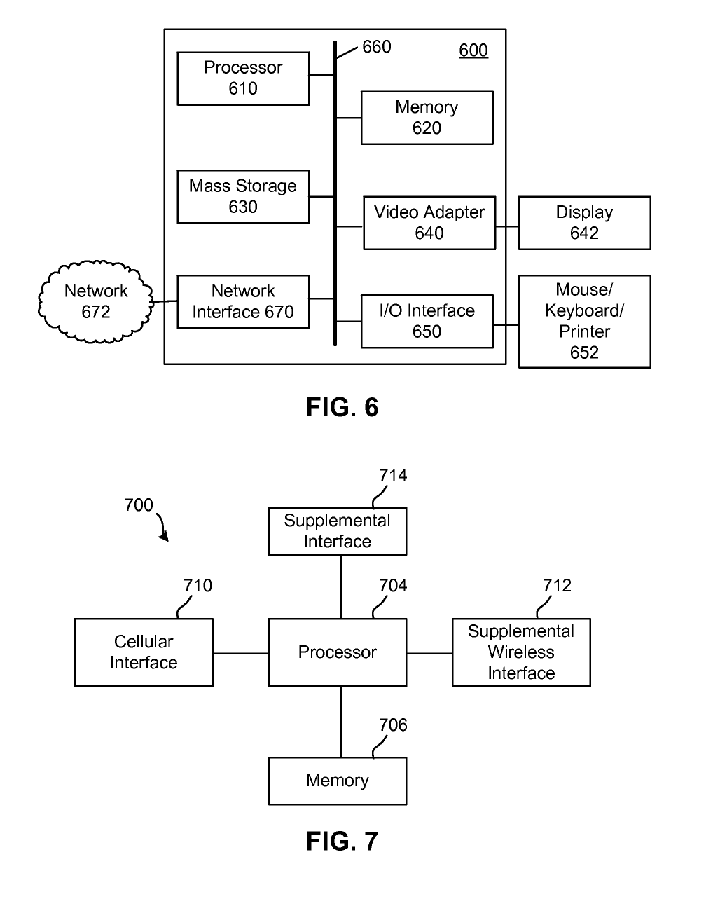

The methods, devices and systems described herein may be used in or with any computing system or device including but not limited to user equipments, mobile devices, node Bs, base stations, network elements, transmission points, machines, chips, etc. For example, FIG. 6 is a block diagram of a processing system 600 that may be used with the methods and devices according to the present disclosure. Specific devices may utilize all of the components shown, or only a subset of the components, and levels of integration may vary from device to device. Furthermore, a device may contain multiple instances of a component, such as multiple processing units, processors, memories, transmitters, receivers, etc. The processing system 600 may comprise a processing unit equipped with one or more input/output devices, such as a speaker, microphone, mouse, touchscreen, keypad, keyboard, printer, display, and the like. The processing system may include one or more of a processor 610, memory 620, a mass storage device 630, a video adapter 640, and an I/O interface 650 connected to a bus 660. In at least one embodiment, processor 610 may be multi-core or a many-core processor, or any other processor having multiple execution units, for example for executing one or more methods according to the present disclosure.

The bus 660 may be one or more of any type of several bus architectures including a memory bus or memory controller, a peripheral bus, video bus, or the like. The memory 620 may comprise any type of system memory such as static random access memory (SRAM), dynamic random access memory (DRAM), synchronous DRAM (SDRAM), read-only memory (ROM), a combination thereof, or the like. In an embodiment, the memory may include ROM for use at boot-up, and DRAM for program and data storage for use while executing programs.

The mass storage device 630 may comprise any type of storage device configured to store data, programs, and other information and to make the data, programs, and other information accessible via the bus. The mass storage device 630 may comprise, for example, one or more of a solid state drive, hard disk drive, a magnetic disk drive, an optical disk drive, or the like.

The video adapter 640 and the I/O interface 650 provide interfaces to couple external input and output devices to the processing system. As illustrated, examples of input and output devices include the display 642 coupled to the video adapter and the mouse/keyboard/printer 652 coupled to the I/O interface. Other devices may be coupled to the processing system, and additional or fewer interface cards may be utilized. For example, a serial interface such as Universal Serial Bus (USB) (not shown) may be used to provide an interface for a printer.

The processing system 600 also includes one or more network interfaces 670, which may comprise wired links, such as an Ethernet cable or the like, and/or wireless links to access nodes or different networks. The network interface 670 may allow the processing system to communicate with remote units or systems via the networks. For example, the network interface 670 may provide wireless communication via one or more transmitters/transmit antennas and one or more receivers/receive antennas. In an embodiment, the processing system 600 may connect to one or more networks, for example to a local-area network or a wide-area network, shown as network 672, for data processing and communications with remote devices, such as other processing systems, the Internet, remote storage facilities, or the like.

FIG. 7 illustrates a block diagram of an embodiment of a communications device or system 700, which may be equivalent to one or more devices (e.g., user equipments, node Bs, base stations, network elements, transmission points, machines, chips, etc.) discussed above. The communications device 700 may include one or more processors 704, such as for example a multi-core or many-core processor, or any other multi execution unit processor or processing system. Communications device 700 may further include a memory 706, a cellular or other wireless interface 710, a supplemental wireless interface 712, and a supplemental interface 714, which may (or may not) be arranged as shown in FIG. 7. The processor 704 may be any component capable of performing computations and/or other processing related tasks, and the memory 706 may be any component capable of storing programming and/or instructions for the processor 704. The cellular interface 710 may be any component or collection of components that allows the communications device 700 to communicate using a cellular or other wireless signal, and may be used to receive and/or transmit information over a cellular or other connection of a cellular or other network. The supplemental wireless interface 712 may be any component or collection of components that allows the communications device 700 to communicate via one or more other wireless protocols, such as a Wi-Fi or Bluetooth protocol, or a control protocol. The device 700 may use the cellular interface 710 and/or the supplemental wireless interface 712 to communicate with any wirelessly enabled component, e.g., a base station, transmission point, network element, relay, mobile device, machine, etc. The supplemental interface 714 may be any component or collection of components that allows the communications device 700 to communicate via a supplemental protocol, including wire-line protocols. In embodiments, the supplemental interface 714 may allow the device 700 to communicate with another component, such as a backhaul network component.

Through the descriptions of the preceding embodiments, the teachings of the present disclosure may be implemented by using hardware only or by using a combination of software and hardware. Software or other computer executable instructions for implementing one or more embodiments, or one or more portions thereof, may be stored on any suitable computer readable storage medium. The computer readable storage medium may be a tangible or in transitory/non-transitory medium such as optical (e.g., CD, DVD, Blu-Ray, etc.), magnetic, hard disk, volatile or non-volatile, solid state, or any other type of storage medium known in the art.

Furthermore, although embodiments have been described in the context of multi-core processors and many-core processors, the scope of the present disclosure is not intended to be limited to such processors. The teachings of the present disclosure may be used or applied in other applications and in other fields. Therefore teachings herein generally apply to other types of processing systems having multiple execution units.

Additional features and advantages of the present disclosure will be appreciated by those skilled in the art.

The structure, features, accessories, and alternatives of specific embodiments described herein and shown in the Figures are intended to apply generally to all of the teachings of the present disclosure, including to all of the embodiments described and illustrated herein, insofar as they are compatible. In other words, the structure, features, accessories, and alternatives of a specific embodiment are not intended to be limited to only that specific embodiment unless so indicated.

Moreover, the previous detailed description is provided to enable any person skilled in the art to make or use one or more embodiments according to the present disclosure. Various modifications to those embodiments will be readily apparent to those skilled in the art, and the generic principles defined herein may be applied to other embodiments without departing from the spirit or scope of the teachings provided herein. Thus, the present methods, systems, and or devices are not intended to be limited to the embodiments disclosed herein. The scope of the claims should not be limited by these embodiments, but should be given the broadest interpretation consistent with the description as a whole. Reference to an element in the singular, such as by use of the article “a” or “an” is not intended to mean “one and only one” unless specifically so stated, but rather “one or more”. All structural and functional equivalents to the elements of the various embodiments described throughout the disclosure that are known or later come to be known to those of ordinary skill in the art are intended to be encompassed by the elements of the claims.

Furthermore, nothing herein is intended as an admission of prior art or of common general knowledge. In addition, citation or identification of any document in this application is not an admission that such document is available as prior art, or that any reference forms a part of the common general knowledge in the art. Moreover, nothing disclosed herein is intended to be dedicated to the public regardless of whether such disclosure is explicitly recited in the claims.

What is claimed:

1. A method for adapting a filter in signal processing, the method comprising:
generating values vᵢ based on values uᵢ in an input signal, the values vᵢ being generated in parallel, where i=0, 1, 2, . . . , N, u_{N}=d, wherein d is an output signal received from the filter;
generating values Γᵢ recursively based on the values vᵢ;
generating values D(i) and L(i) based on values sᵢ and the values Γᵢ, the values D(i) and L(i) being generated in parallel, where the values sᵢ are conjugates or complex conjugates of the values uᵢ; and
generating a signal W according to the values uᵢ, D(i) and L(i).

2. The method of claim 1, wherein the generating values vᵢ involves generating square values of input signal values uᵢ.

3. The method of claim 2, wherein the generating values Γᵢ involves generating values Γᵢ according to equation Γᵢ=Γᵢ₋₁+vᵢ₋₁, where Γ₀=1 and i=1, 2, 3, . . . , N.

4. The method of claim 3, wherein the generating values D(i) and L(i) involves generating values D(i) according to equation D(i)=AᵢBᵢ₊₁ and generating values L(i) according to equation L(i)=sᵢBᵢBᵢ₊₁ wherein
$${A}_{i} = \sqrt{{Γ}_{i}} , \\ {B}_{i} = \frac{1}{\sqrt{{Γ}_{i}}} ,$$
where i=0, 1, 2, 3, . . . , N.

5. The method of claim 4, wherein the signal W is generated according to equation
$$W ( i , j ) = \{ \begin{matrix}D ( i ) & i = j \\ - {u}_{j} \cdot D ( i ) \cdot ( {\sum }_{m = 0}^{j - 1} W ( i , m ) \cdot L ( m ) ) & i < j \\ 0 & otherwise\end{matrix}$$

6. The method of claim 5, further comprising outputting the signal W to the filter.

7. An apparatus for adapting a filter in signal processing, the apparatus comprising:
a processing module comprising:
a first module for receiving value d from the filter and values uᵢ in an input signal; and
a second module for generating a signal W and comprising multiple execution units, the second module configured to:
generate values vᵢ based on values uᵢ, the values vᵢ being generated in parallel using at least some of the multiple execution units, where i=0, 1, 2, . . . , N, u_{N}=d;
generate values Γᵢ recursively based on the values vᵢ;
generate values D(i) and L(i) based on values sᵢ and the values Γᵢ, the values D(i) and L(i) being generated in parallel using at least some of the multiple execution units, where the values sᵢ are conjugates or complex conjugates of the values uᵢ; and
generate the signal W according to the values uᵢ, D(i) and L(i).

8. The apparatus of claim 7, wherein the second module is configured such that the generating values vᵢ involves generating square values of input signal values uᵢ.

9. The apparatus of claim 8, wherein the second module is configured such that the generating values Γᵢ involves generating values Γᵢ according to equation Γᵢ=Γᵢ₋₁+vᵢ₋₁, where Γ₀=1 and i=1, 2, 3, . . . , N.

10. The apparatus of claim 9, wherein the second module is configured such that the generating values D(i) and L(i) involves generating values D(i) according to equation D(i)=AᵢBᵢ₊₁ and generating values L(i) according to equation L(i)=sᵢBᵢBᵢ₊₁ where
$${A}_{i} = \sqrt{{Γ}_{i}} , \\ {B}_{i} = \frac{1}{\sqrt{{Γ}_{i}}}$$
and i=0, 1, 2, 3, . . . , N.

11. The apparatus of claim 10, wherein the second module is configured such that the generating signal W involves generating signal W according to equation:
$$W ( i , j ) = \{ \begin{matrix}D ( i ) & i = j \\ - {u}_{j} \cdot D ( i ) \cdot ( {\sum }_{m = 0}^{j - 1} W ( i , m ) \cdot L ( m ) ) & i < j \\ 0 & otherwise\end{matrix}$$

12. The apparatus of claim 11 configured to output the generated signal W to the filter.

13. A computer-readable storage medium storing instructions that when executed by multiple execution units cause the multiple execution units to perform operations for adapting a filter in signal processing, the operations comprising:
generating values vᵢ based on values uᵢ in an input signal, the vᵢ values being generated in parallel using at least some of the multiple execution units, where i=0, 1, 2, . . . , N, u_{N}=d, wherein d is an output signal received from the filter;
generating values Γᵢ recursively based on the values vᵢ;
generating values D(i) and L(i) based on values sᵢ and the values Γᵢ, the values D(i) and L(i) being generated in parallel using at least some of the multiple execution units, where the values sᵢ are conjugates or complex conjugates of the values uᵢ; and
generating a signal W according to the values uᵢ, D(i) and L(i).

14. The computer-readable storage medium of claim 13, wherein the generating values vᵢ involves generating square values of input signal values uᵢ.

15. The computer-readable storage medium of claim 14, wherein the generating values Γᵢ involves generating values Γᵢ according to equation Γᵢ=Γᵢ₋₁+vᵢ₋₁, where Γ₀=1 and i=1, 2, 3, . . . , N.

16. The computer-readable storage medium of claim 15, wherein the generating values D(i) and L(i) involves generating values D(i) according to equation D(i)=AᵢBᵢ₊₁ and generating values L(i) according to equation L(i)=sᵢBᵢBᵢ₊₁ wherein
$${A}_{i} = \sqrt{{Γ}_{i}} , \\ {B}_{i} = \frac{1}{\sqrt{{Γ}_{i}}} ,$$
where i=U, 1, 2, 3, . . . , N.

17. The computer-readable storage medium of claim 16, wherein the signal W is generated according to equation
$$W ( i , j ) = \{ \begin{matrix}D ( i ) & i = j \\ - {u}_{j} \cdot D ( i ) \cdot ( {\sum }_{m = 0}^{j - 1} W ( i , m ) \cdot L ( m ) ) & i < j \\ 0 & otherwise\end{matrix}$$

18. The computer-readable storage medium of claim 17, wherein the operations further comprise outputting the signal W to the filter.
